(19) United States
(12) Patent Application Publication
(10) Pub. No.: US 2012/0067337 A1
(43) Pub. Date: Mar. 22, 2012

(54) Rotatable Panels on an Exterior of a Structure that Directs Solar Energy within the Structure

(76) Inventors: David R. Hall, Provo, UT (US); Craig Boswell, Provo, UT (US); Eric Gardner, (US); David Allred, Provo, UT (US)

(21) Appl. No.: 12/894,491

(22) Filed: Sep. 30, 2010

Related U.S. Application Data
(63) Continuation of application No. 12/886,724, filed on Sep. 21, 2010.

(51) Int. Cl. F24J 2/38; H01L 31/00; F24J 2/46

(52) U.S. Cl. 126/600; 126/623; 136/252

(57) ABSTRACT

In one aspect of the present invention, a structure comprises a plurality of reflective panels secured to the structure. Each reflective panel has an axis of rotation. A processing element controls an orientation of each reflective panel about its axis of rotation to direct solar energy within the structure.

### CROSS REFERENCE TO RELATED APPLICATIONS

This application is a continuation of U.S. patent application Ser. No. 12/886,724, which was filed on Sep. 21, 2010 and is herein incorporated by reference for all that it discloses.

### BACKGROUND OF THE INVENTION

This invention relates to methods of utilizing solar energy. Solar energy can provide energy for many different residential, commercial, and industrial applications, without the use of fossil fuels and the associated economic and environmental disadvantages. Solar energy installations typically require a large area to collect and focus solar energy on a certain solar application. Some solar energy applications may be constrained by the area available for energy collection.

Efforts to increase the economic and spatial efficiency of solar energy collection are disclosed in the prior art. U.S. Pat. No. 7,531,740 which is herein incorporated by reference for all that it contains, discloses a photovoltaic module generates electrical power when installed on a roof. The module is constructed as a laminated sandwich having a transparent protective upper layer adhered to a photovoltaic layer. The photovoltaic layer is adhered to a rigid layer formed from a fiber reinforced plastic. The laminated sandwich has a frame around the perimeter. The laminated panel has a layer of double stick tape on the bottom to adhere the panel to the surface of a roof.

U.S. Patent Application Publication No. 2007/0074754 which is herein incorporated by reference for all that it contains to Farquhar discloses a photovoltaic roofing system and a method of installing the photovoltaic ridge cap structure have been provided. The photovoltaic roofing system includes a ridge cap adapted to cover a ridge of a roof structure. The system also includes at least one photovoltaic cell disposed within the ridge cap. The method of installing a photovoltaic ridge cap structure includes mounting the ridge cap over multiple photovoltaic cells along a ridge of a roof structure. The method further includes routing electrical leads from each photovoltaic cell through one or more opening along the ridge of the roof structure.

U.S. Patent Application Publication No. 2007/0074753 to Altali which is herein incorporated by reference for all that it contains, discloses the present invention provides a motor driven by shape memory alloys for use in a variety of applications. In the disclosed embodiment, the motor is used to drive a photovoltaic panel so that the panel may remain in appropriate alignment with the sun throughout the day. In such a configuration, the motor assembly relies upon the intrinsic properties of shape memory alloys, in conjunction with a spring assembly, in order to generate sufficient torque in order to rotate the photovoltaic panel. In order to control the orientation of the panel, the system relies upon a sun tracking mechanism which includes an analog sensor circuit, a plurality of phototransistors and a power source. Accordingly, the device is able to rotate the photovoltaic panel in discrete and precise increments as the day progresses.

U.S. Pat. No. 4,271,818 to Hastwell, which is herein incorporated by reference for all that it contains discloses a roofing structure in which roofing panels support solar collector plates in cavities in the roofing panels, or formed on the roofing panels, above which are shielding panels which pass solar radiation but prevent water flow into the cavities, so that the solar collector plates are positioned between the shielding panels and the roofing panels with the roofing panels being thermally insulated on their undersides to pass back heat which passes through the solar collector plates.

### BRIEF SUMMARY OF THE INVENTION

In one aspect of the present invention, a structure comprises a plurality of reflective panels secured to the structure. Each panel has an axis of rotation, and a processing element controls an orientation of each reflective panel about its axis of rotation to direct solar energy within the structure. The panels may be controlled individually or in groups. In some embodiments, all of the panels are controlled as a single group.

Solar energy applications within the structure may comprise solar energy heated working fluids; agricultural operations such as a greenhouse, algae farm, or fish hatchery; or may comprise photovoltaic cells for direct electricity generation. The reflective panels may comprise reflective surfaces that are parabolic, curved, planer or combinations thereof. The reflective panels may be secured to an exterior portion of the building, such as a roof or wall. In some cases, the panels are secured below a transparent roof or inside a window of the structure.

A processing element that controls the orientation of the panels may comprise an electrical microprocessor. The microprocessor may be in communication with several electrical sensors, such as one or more photo-sensitive electrical elements such as photoresistors, and one or more temperature sensitive electrical elements such as thermocouples or thermistors. The electrical microprocessor may be in communication with electrical servo motors, electrical linear actuators, or solenoids. The servo motors, linear actuators, or solenoids may be in mechanical communication with the reflective panels, and may cause rotation about the axis of rotation.

In some embodiments, the panels may be constructed from steel, stainless steel, aluminum, magnesium, or other metals or metal alloys. The panels may be polished to enhance reflectivity. In other embodiments, the panels may comprise wood, plastic, or composite materials and may comprise a metal coating or metal film. Other materials may be used as a reflective surface. The reflective panels may comprise an elongated shape, and each reflective panel may be supported at opposite ends by pivots connected to the structure. The panels may also be made a translucent material that allows some light wavelengths to pass through while reflecting other light wavelengths. In some embodiments, the translucent materials may include dichroic and/or dielectric coatings.

In another aspect of the invention, a method of utilizing solar power comprises the following steps: providing a building comprising rotatable reflective panels secured to the building and one or more solar powered operations within the building, prioritizing the solar energy applications, and rotating the reflective panels to focus solar energy reflected from the reflective panels to one or more solar powered operations according to priority.

### BRIEF DESCRIPTION OF THE DRAWINGS

FIG. 1 is a perspective view of an embodiment of a structure.

FIG. 2 is a cross-sectional view of another embodiment of a structure.

FIG. 3 is a cross-sectional view of another embodiment of a structure.

FIG. 4 is a cross-sectional view of another embodiment of a structure.

FIG. 5 is a cross-sectional view of another embodiment of a structure.

FIG. 6 is a cross-sectional view of another embodiment of a structure.

FIG. 7 is a perspective view of another embodiment of a structure.

FIG. 8a is a cross-sectional view of another embodiment of a structure.

FIG. 8b is a cross-sectional view of another embodiment of a structure.

FIG. 9 is a perspective view of an embodiment of a reflective panel.

FIG. 10 is a perspective view of another embodiment of a reflective panel.

FIG. 11a is a cross-sectional view of another embodiment of a reflective panel.

FIG. 11b is a cross-sectional view of another embodiment of a reflective panel.

FIG. 11c is a cross-sectional view of another embodiment of a reflective panel.

FIG. 11d is a cross-sectional view of another embodiment of a reflective panel.

FIG. 11e is a cross-sectional view of another embodiment of a reflective panel.

FIG. 12 is a block diagram of an embodiment of a processing element.

FIG. 13 is an embodiment of a method of utilizing solar energy.

### DETAILED DESCRIPTION OF THE INVENTION AND THE PREFERRED EMBODIMENT

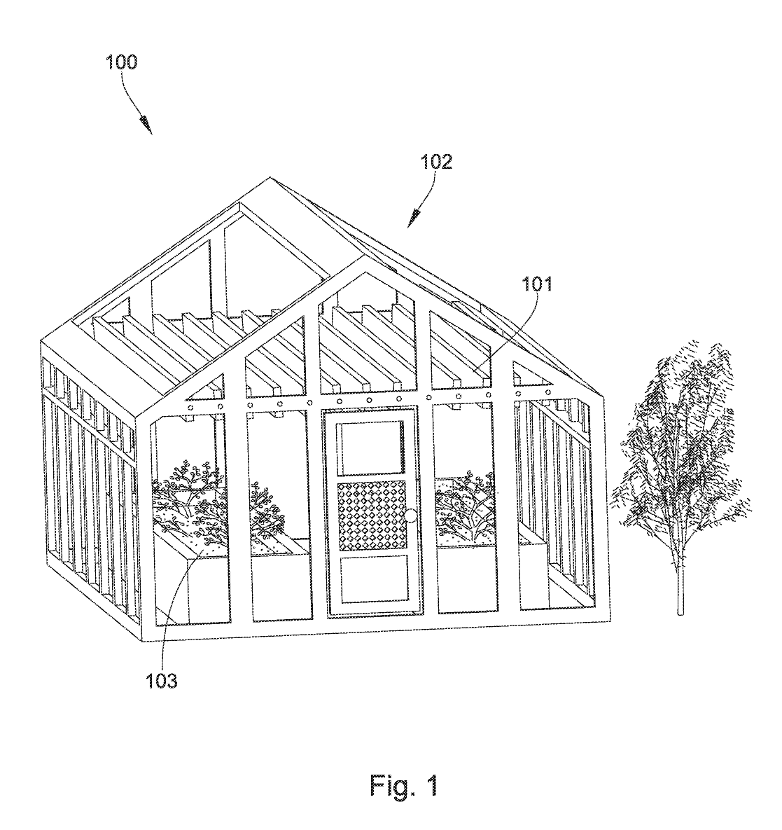

Referring now to the figures, FIG. 1 discloses an embodiment of a structure 100. The structure 100 may comprise residential living space, commercial, agricultural, or industrial operations, and/or combinations thereof. Any number of solar applications may be within the structure. In this embodiment, an agricultural operation is disclosed. Other solar applications may include heating fluids to store thermal energy or photovoltaic applications.

A plurality of reflective panels 101 is secured to the structure. These panels may direct solar energy to any of the solar application within the structure. In some embodiments, the panels may be disposed on an exterior portion 102 of the structure 100. In the embodiment of FIG. 1, the panels are secured to the structure beneath the roof. The roof may be transparent allowing all or some light to pass through. A transparent roof with the panels disposed underneath allows the roof to block rain and snow from entering the structure while still controlling the light with the panels.

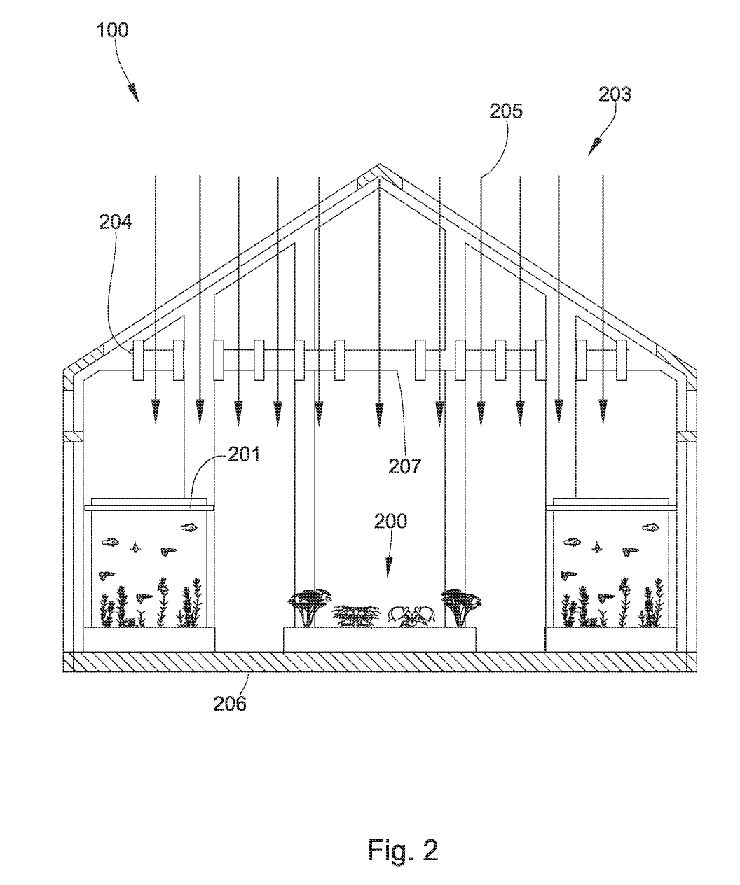

FIG. 2 is a cross sectional view of an embodiment of a structure 100. The structure 100 comprises multiple solar energy applications including an agricultural application 200 and an aquarium operation 201. In this embodiment, the reflective panels 204 are shown oriented vertically, allowing solar radiation 205 to enter the structure 100 substantially normal to a floor 206 of the structure to the agricultural application. As the sun move during the day, the panels may move as necessary to continue to direct sun to agricultural application. However, a control system may direct the solar energy to other applications within the structure throughout the day as desired.

The agricultural application 200 may comprise food crops, material crops, or other plants that rely on photosynthetic. Food crops may include grains, fruits, vegetables, tubers, legumes, or other comestibles. Material crops may include bamboo, cotton, flax, jute, sisal, or other plants. Crops, such as these, rely on solar energy to provide energy for photosynthetic. In this embodiment, the structure 100 functions to protect such plants from extreme heat, cold, and wind, and solar energy is guided by the panels to the plants. In some embodiments, the agricultural operation may comprise hydroponic or aeroponic growing methods.

Also in this embodiment, the structure houses an aquarium operation 201. Many fish, mollusks and crustaceans raised for consumption require heated water and light to survive. Solar energy entering the structure 100 through the roof portion 203 may heat the water and provide the required light. In other embodiments, the structure 100 may comprise other aquaculture operations such as algae farming for food, oil, or biomass. Further, the water in the aquarium operation may store heat from the sun. The solar energy stored in the aquarium tanks may radiate out when sunlight is not available and keep the agriculture operation heated.

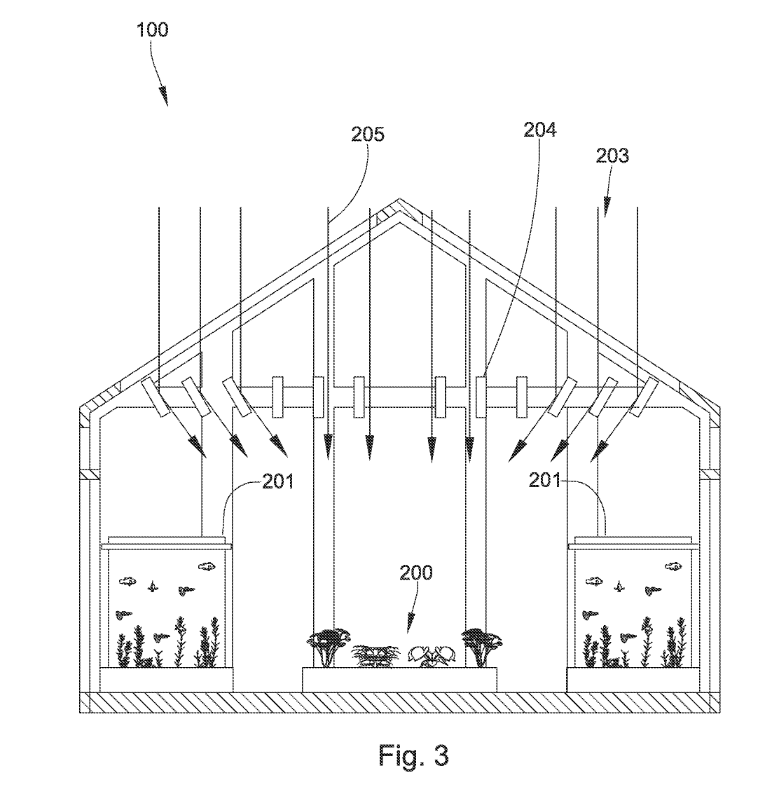

FIG. 3 discloses some of the reflective panels rotated to direct solar energy primarily to agricultural operation 200. Aquarium operations 201 are, thus, shielded from direct solar exposure, while agricultural operation 200 receives an increased concentration of solar energy.

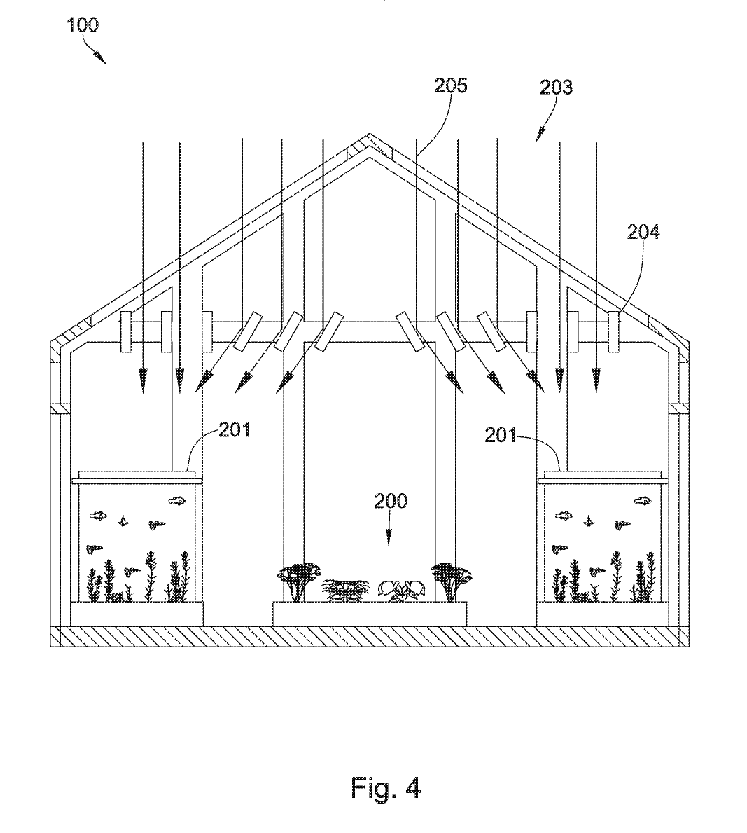

FIG. 4 discloses a structure 100 where the reflective panels 204 are rotated to direct solar radiation 205 primarily to the aquarium operations 201, while partially shielding agricultural operation 200 from direct radiation. Agricultural operation 200 may receive diffuse solar radiation reflected from surfaces within the structure.

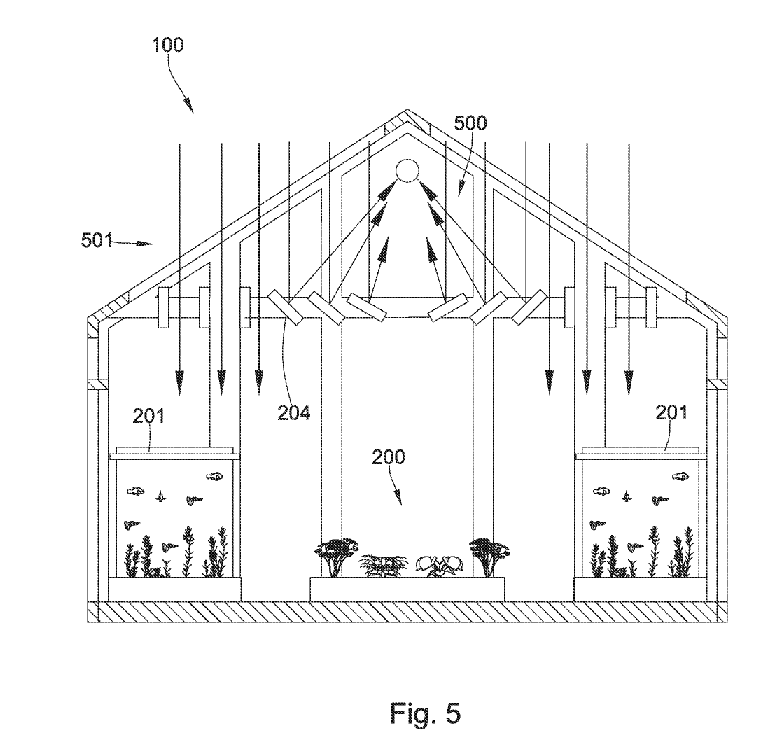

FIG. 5 discloses a structure 100 where the reflective panels 204 are rotated to direct a portion 500 of solar radiation to a conduit 202 carrying a heat transfer fluid, while another portion 501 is allowed to pass through vertically oriented reflective panels to directly impinge on the aquarium operations 201.

The heated fluid may be used for interior space heating by directing the fluid through a radiator or other heat exchanger, through a surface of the structure such as a floor or wall, or by heating air in a forced air ventilation system. Other embodiments may use the heated fluid for steam generation to drive a turbine connected to an electrical generator. After heat is transferred from the fluid to heat air or water for steam, the fluid may be directed back through a portion of conduit 202 exposed to solar radiation 205.

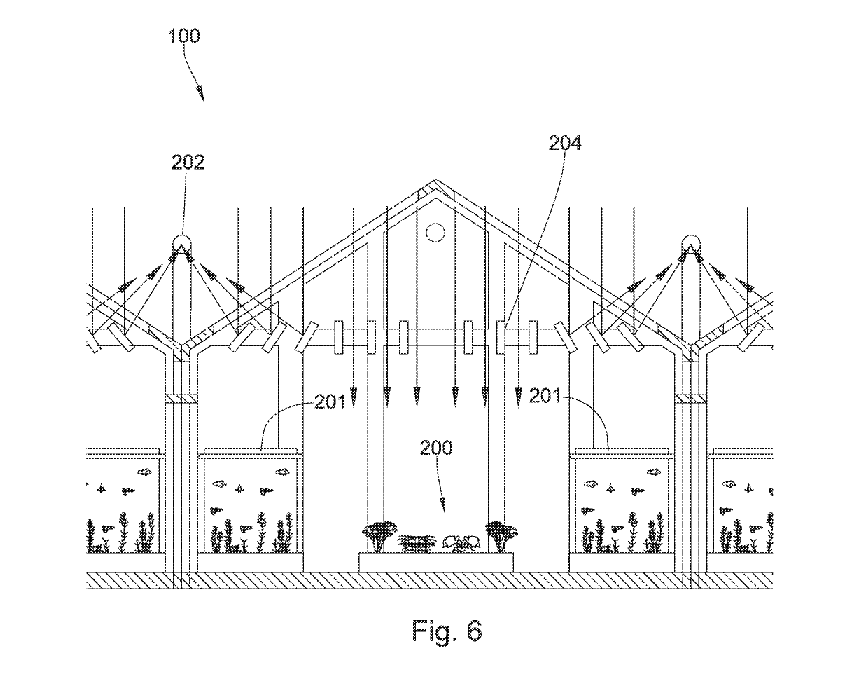

FIG. 6 discloses a structure 100 where the reflective panels 204 are rotated to direct solar energy to conduits 202 carrying heat transfer fluid on the outside of the structure. Vertically oriented reflective panels allow solar energy to reach agricultural operation 200 directly.

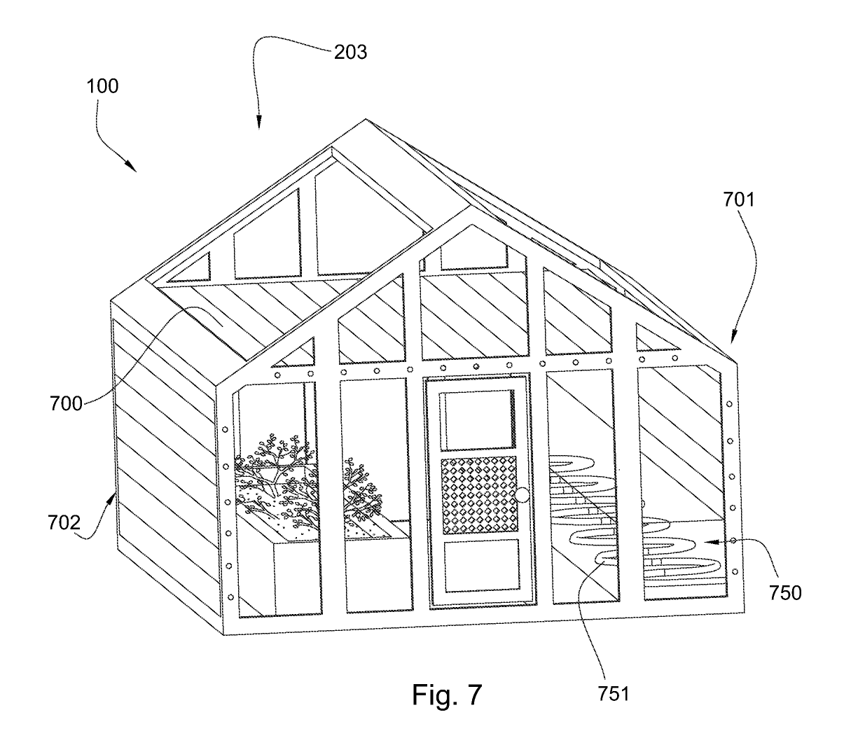

In the embodiment of FIG. 7, reflective panels 204 are disposed underneath the roof 701 and are also incorporated into the wall 702 of a structure 100. The panels under the roof and in the wall are both depicted in a closed arrangement, which blocks solar radiation from entering the structure. However, each panel may be individually controlled, thereby, permitting some of the panels to move and direct solar radiation to wherever desired.

Liquids such in tanks 750, such as water in an aquarium, may store solar energy. When the panels are in a closed arrangement, the solar energy may radiate out of the tanks and warm the interior of the structure. In some embodiments, heat exchangers, such as tubes, may draw the solar energy out of the tanks and take the heat to another location.

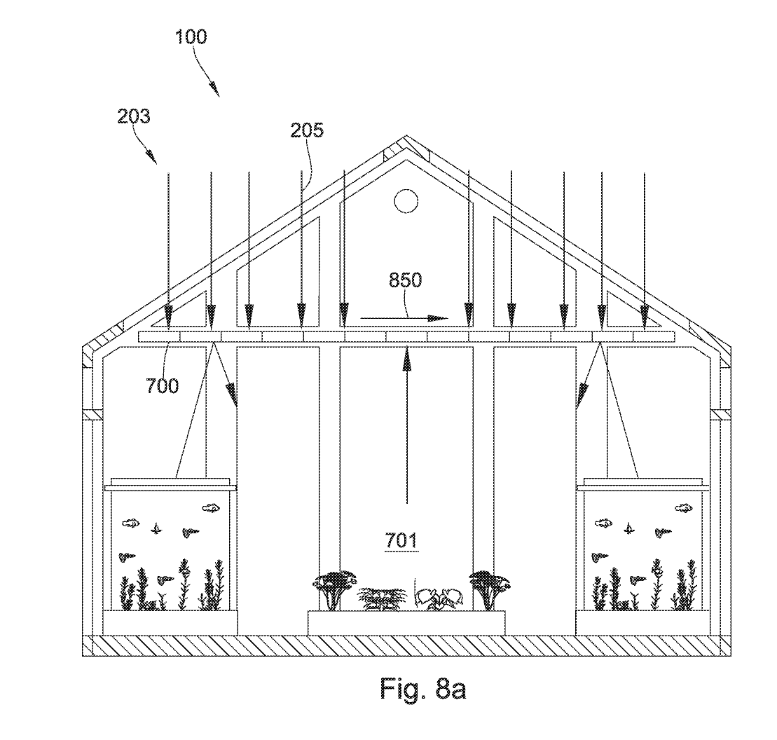

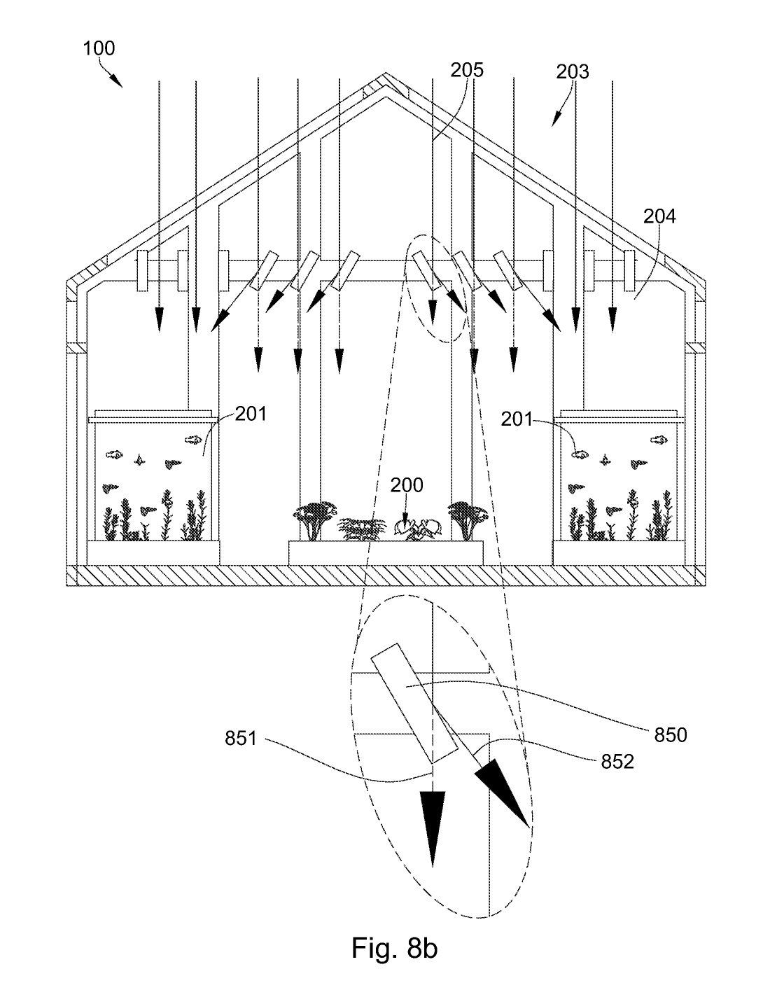

FIG. 8a discloses an array of photovoltaic cells 700 disposed underneath the roof 203 and incorporated into the rotatable panels. In this embodiment, photovoltaic panels 700 comprise a dye-sensitized photovoltaic liquid intermediate two glass panels. The photovoltaic panels absorb a portion of the solar energy incident on the structure and generate electrical current indicated by 850. The glass panels may be treated with partially reflective materials. In some embodiments, the partially reflective materials may comprise polarizing filters or electrically actuated filters.

In some embodiments, the panels incorporate the photovoltaic material on one side of the panel and incorporate a reflective surface on the other side. In the embodiment of FIG. 8a, a reflective surface of the panels is facing the interior of the structure and reflecting heat radiated from the tanks back into the interior. Thus, the reflective surfaces may more efficiently control the interior's temperature.

FIG. 8b discloses some panels that are configured to reflect a range of light wavelengths, while allowing another range of wavelengths to pass through. In some situations, light of certain wavelengths may be better suited for different solar applications within the structure. For example, visible light may be better suited for agricultural applications involving photosynthesis, while shorter wavelengths may be better suited for heat storage. Thus, the translucent panels 850 may allow visible light 851 to pass through directly to the agricultural applications, while reflecting the shorter wavelengths 852 to the aquariums for solar radiation storage.

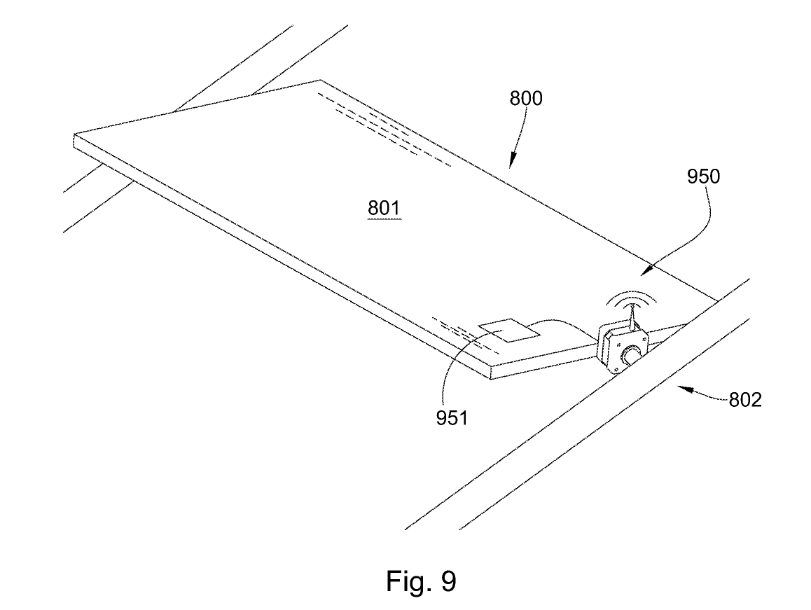

FIG. 9 discloses a reflective panel 800 with a planer geometry and a reflective surface 801. A servo motor 802 may control the rotational position of the reflective panel. Preferably, the motor receives its electrical power through a photovoltaic material 951 incorporated on the reflective surface, and the motor also receives a wireless, control signal 950 from a process element. In some embodiments, the servo motor shaft may be attached directly to the panel, or it may rotate the panel through a chain set, gear set, a belt and pulley, or combinations thereof.

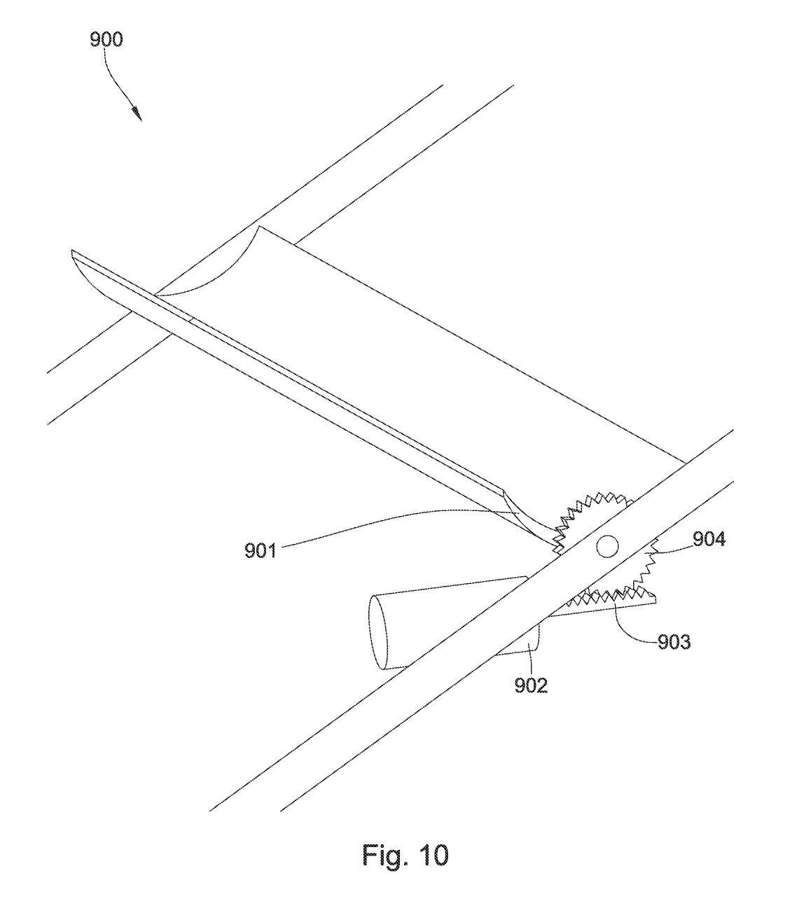

FIG. 10 discloses a reflective panel with a curved geometry. In some embodiments, the curved geometry may comprise a curved cross section 901, preferably a parabolic cross section. Parabolic or other curved cross sections may focus reflected solar radiation more effectively and reduce diffusion. The focal point of the parabolic or curved cross section may be chosen to maximize reflected energy at any particular solar application, such as a heat transfer fluid carrying conduit, an agricultural operation, or any other solar energy application. As the reflective panel 900 rotates, the focal point of the parabolic or other curved geometry traces a circular arc. Each reflective panel may comprise a different distance from the reflector to the focal point, allowing each reflective panel to focus solar energy on a single application, such as the conduit containing heat transfer fluid. In some embodiments, a reflective surface may be incorporated into both sides of the panels. Each side may comprise a different curvatures resulting in different focal points. Thus, one curve may be optimized to concentrate solar energy to one solar application, while the other curve is optimized to concentrate solar energy to another application.

In this embodiment, the reflective panel 900 is rotated by a linear actuator 902. Linear actuator 902 may comprise an electrical solenoid or a hydraulic cylinder driving a rack gear 903 in communication with a pinion gear 904 attached to the reflective panel 900. Other embodiments may comprise a mechanical linkage or direct mechanical connection between the panel 900 and the linear actuator 902.

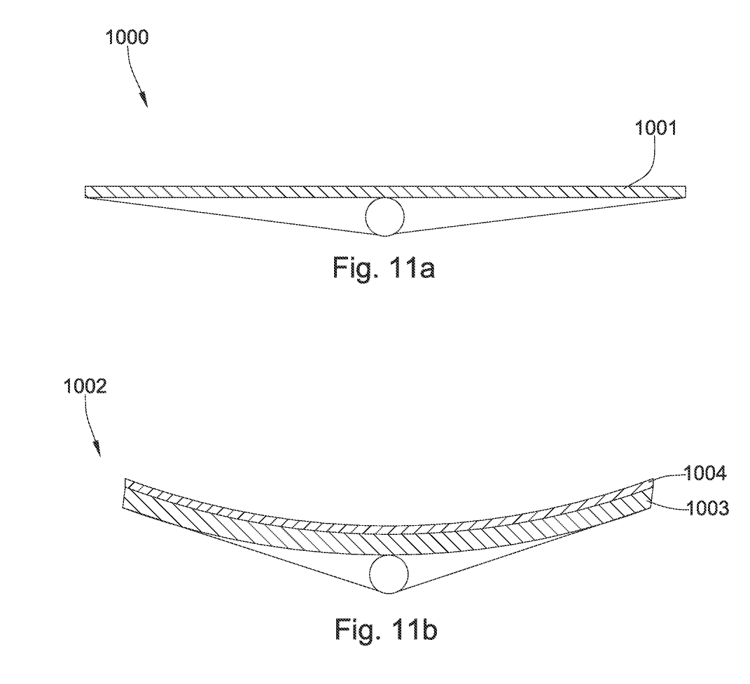

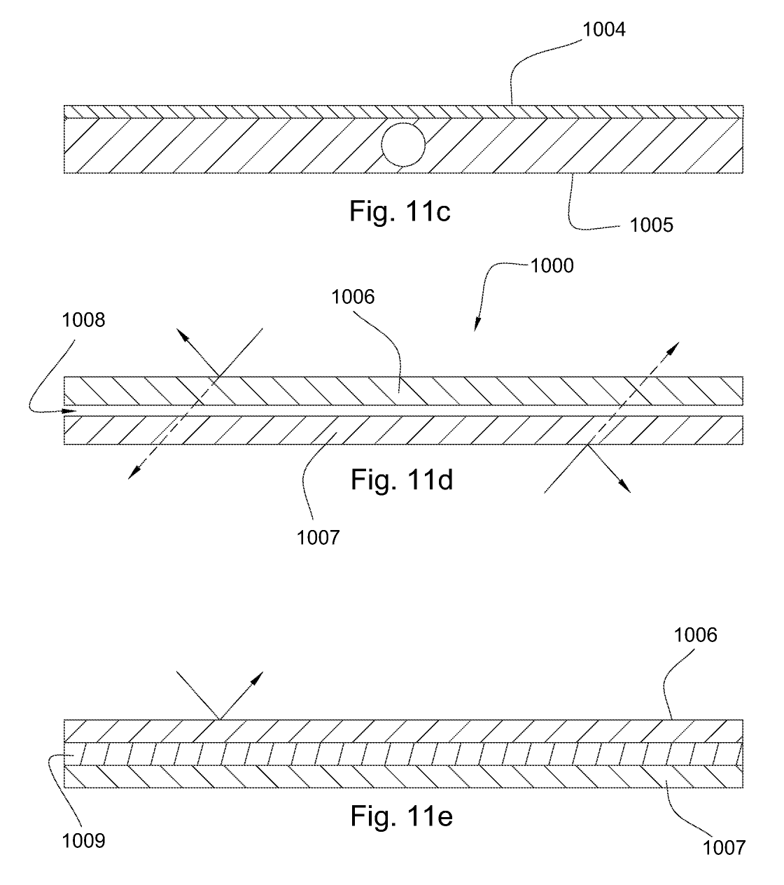

FIG. 11a discloses a reflective panel 1000 with a planer surface 1001. The panel may be constructed from a metal or metal alloy such as aluminum, carbon steel, or stainless steel. Aluminum panels may comprise a corrosion resistant surface finish such as anodizing or electro-plating with nickel or chromium. The surface 1001 may be polished prior to finishing. Carbon steel panels may be polished and electroplated with nickel, chromium, or combinations thereof.

FIG. 11b discloses a reflective panel 1002 with a structural substrate 1003 that may be made from polymers such as polyvinyl chloride, high or low density polyethylene, other polymers, or composite materials such as fiberglass, carbon fiber, or aramid fiber with a resin binder, or natural wood. The structural substrate 1003 may comprise a curved cross section such as a parabolic cross section. A layer of reflective material 1004 may be disposed on the structural substrate 1003. The reflective material may comprise polished sheet metal or metal foil affixed atop the substrate. In some embodiments, the structural substrate may be coated with metal by chemical or physical deposition processes. Other embodiments may comprise polymer films with metal foil or embedded metal particles.

FIG. 11c discloses an embodiment of a reflective panel 1000 comprising a reflective side 1004 and an insulated side 1005. During times of little or no solar radiation, the reflective side can be positioned inward to reflect radiant heat back into a structure, while the insulation slows heat transfer from conduction and convection.

FIG. 11d discloses an embodiment of a reflective panel 1000 comprising two panes 1006 and 1007 separated by an air gap 1008. Panes 1006 and 1007 may be adapted to allow different wavelengths to pass through while reflecting other wavelengths. Thus, by rotating the panel, the different ranges of wavelengths may be more accurately controlled. The air gap may act as a thermal insulator because air may have a lower thermal conduction coefficient that the panel's panes.

FIG. 11e disclose a panel with opposing panes 1006, 1007, with an opaque insulator 1009 between them.

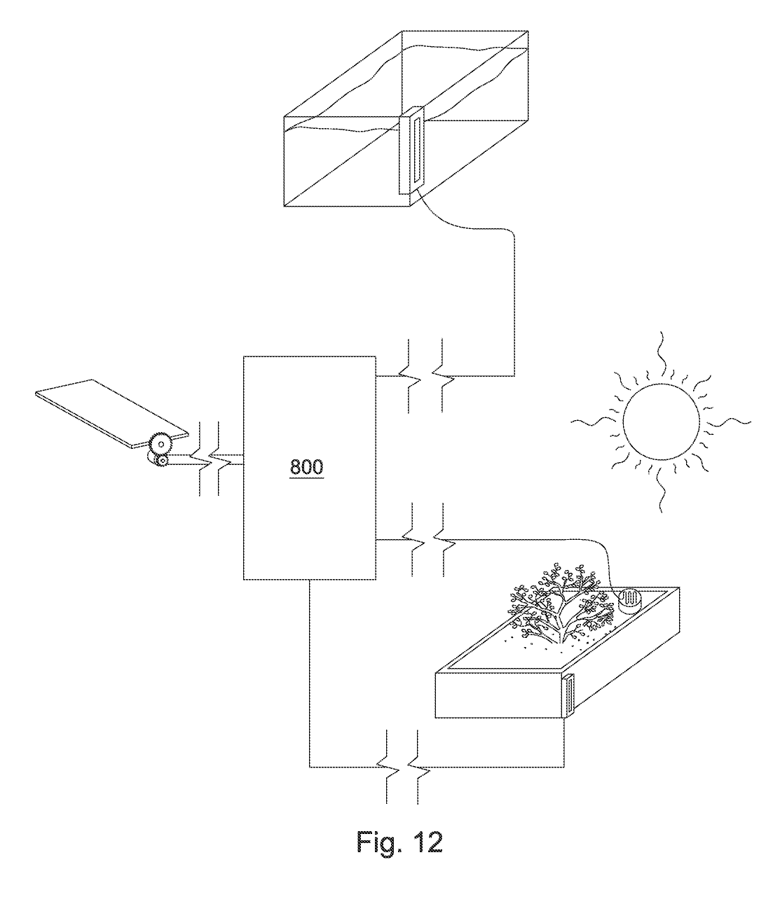

FIG. 12 discloses a processing element 1100 that may comprise an electrical microprocessor in communication with multiple sensing elements such as temperature sensitive elements, light sensitive elements, and position sensitive elements. The temperature sensitive elements may comprise thermocouples, thermistors, or other devices that produce an electrical signal related to temperature. These devices may be used to detect critical temperatures associated with the solar energy applications, such as aquarium water temperature, agricultural operation soil temperature, heat transfer fluid temperature, or air temperature inside the structure. The light sensitive elements may comprise a photoresistor or other light sensitive device, and may be used to detect levels of solar radiation impinging various solar energy applications. Additionally, the light sensitive elements may be used to detect the position of the sun relative to the structure and the reflective panels.

The processing element 1100 may collect data from the temperature sensitive elements, the light sensitive elements, and the position sensitive elements. This data may be processed and used to create output data. The output data may be transmitted to servo motors or linear actuators that control the rotation of the reflective panels to reflect solar energy according to the temperature, solar energy exposure, and solar energy requirements of the various solar energy applications. The duration and magnitude of the temperature and/or solar radiation be used collectively to estimate the amount of heat of solar radiation that has been absorbed in each application. In some cases, the solar applications may require an optimal amount of solar radiation, and the controller may prevent over or under solar exposure. The processing element may also compare the solar exposure received by each of the applications and adjust solar distribution based on the amount of solar radiation available and needs of the various applications.

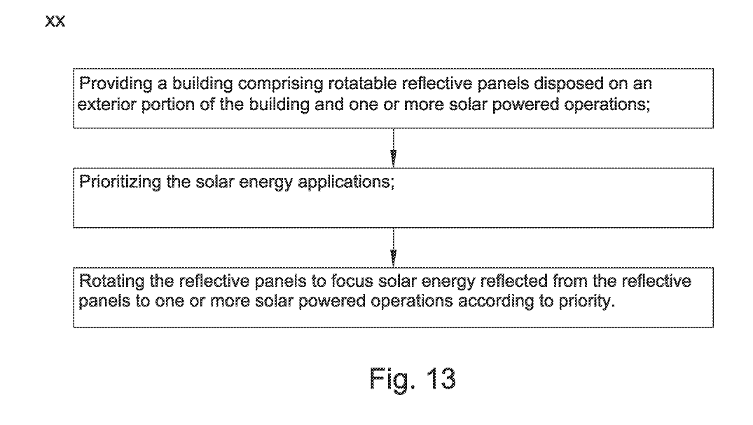

FIG. 13 discloses a method 1200 of utilizing solar power, comprising: providing 1201 a building comprising rotatable reflective panels disposed on an exterior portion of the building and one or more solar powered operations, prioritizing 1202 the solar energy applications, and rotating 1203 the reflective panels to focus solar energy reflected from the reflective panels to one or more solar powered operations according to priority.

Whereas the present invention has been described in particular relation to the drawings attached hereto, it should be understood that other and further modifications apart from those shown or suggested herein, may be made within the scope and spirit of the present invention.

What is claimed is:

1. A structure, comprising:
a plurality of reflective panels secured to the structure; and
at least one of the panels is configured to reflect a first range of solar radiation wavelengths while allowing a second range of solar radiation wavelengths to pass through.

2. The structure of claim 1, wherein the structure further comprises a processing element that controls an orientation of each reflective panel to direct solar radiation within the structure.

3. The structure of claim 1, wherein the second range of solar radiation wavelengths includes visible light.

4. The structure of claim 1, wherein the first range of solar radiation wavelengths are shorter than the second range of solar radiation wavelengths.

5. The structure of claim 1, wherein the at least one of the reflective panel comprises an air gap between two panes.

6. The structure of claim 5, wherein the two panes are configure to reflect a different range of solar radiation.

7. The structure of claim 1, wherein the at least one of the reflective panel comprises a translucent material.

8. The structure of claim 1, wherein the at least one of the reflective panel comprises a dichroic coating.

9. The structure of claim 1, wherein the at least one of the reflective panel comprises a dielectric coating.

10. The structure of claim 1, wherein the at least one of the reflective panel is configured to direct solar radiation to a photovoltaic cell located within the structure.

11. The structure of claim 1, wherein the at least one of the reflective panel is configured to direct solar radiation to an agricultural operation located within the structure.

12. The structure of claim 1, wherein the at least one of the reflective panel is configured to direct solar radiation to a working fluid located within the structure.

13. The structure of claim 1, wherein one or more of the reflective panels comprises a curved reflective surface.

14. The structure of claim 1, wherein one or more of the reflective panels comprises a planer reflective surface.

15. The structure of claim 1, wherein the reflective panels are secured to a roof of the structure.

16. The structure of claim 1, wherein the reflective panels are secured under a roof of the structure.

17. The structure of claim 1, wherein the reflective panels are secured to a wall of the structure.
